(19) United States
(12) Patent Application Publication
(10) Pub. No.: US 2011/0309435 A1
(43) Pub. Date: Dec. 22, 2011

(54) BURIED GATE SEMICONDUCTOR DEVICE AND METHOD OF MANUFACTURING THE SAME

(75) Inventors: Kyung Ho HWANG, Yongin-si (KR); Ji Min LIM, Seoul (KR)

(73) Assignee: Hynix Semiconductor Inc., Icheon-si (KR)

(21) Appl. No.: 12/979,088

(22) Filed: Dec. 27, 2010

(30) Foreign Application Priority Data
Jun. 16, 2010 (KR) 10-2010-0057122

(51) Int. Cl. H01L 29/78; H01L 21/28

(52) U.S. Cl. 257/330; 438/589; 257/E29.262; 257/E21.19

(57) ABSTRACT

A semiconductor device includes a buried gate in a semiconductor substrate, and a nitride layer, over at least the buried gate, whose upper portion is at substantially the same height as an upper portion of a peripheral bit line, where the peripheral bit line is over an interlayer insulating layer. The thickness of the nitride layer is substantially equal to the stacked thickness of the peripheral bit line and the interlayer insulating layer.

### CROSS-REFERENCES TO RELATED APPLICATION

The present application claims priority to Korean patent application number 10-2010-0057122, filed on 16 Jun. 2010, which is incorporated by reference in its entirety.

### BACKGROUND OF THE INVENTION

The inventive concept relates to a semiconductor device and a method of manufacturing the same, and more particularly, to a buried gate semiconductor device and a method of manufacturing the same.

One method of fabricating semiconductor devices is to substitute the recess gate for the prior planar gate having a planar channel. The recess gate is formed within a recess disposed in a semiconductor substrate to form a channel region along the curvature of the recess. Furthermore, the buried gate which is entirely buried within the recess is developed, besides the recess gate.

The buried gate is completely buried under the surface of the semiconductor substrate, so that the length and width of the channel are ensured as well as the parasitic capacitance occurred between the gate (word line) and the bit line can be reduced by about 50% as compared with the prior recess gate.

However, in the entire structure of a cell region and a peripheral region of the semiconductor memory device having the buried gate, because the empty space remains in the cell region by the height of the gate formed in the peripheral region, it is mainly discussed how to make use of the height difference. In the prior art, the space in the cell region corresponding to the height of the peripheral gate remains in an unoccupied state.

In recent years, a GBL (gate bit line) method where the gate in the peripheral region and a bit line in the cell region are simultaneously formed. However, when the gate in the peripheral region and the bit line in the cell region are simultaneously formed, there may be a height difference between the cell region and the peripheral region.

FIG. 1 is a sectional view of a semiconductor device according to the prior art. Referring to FIG. 1, a buried gate 120 is disposed to be buried in a semiconductor substrate 110 of a cell region and a bit line 130 in the cell region and a gate 140 in a peripheral region are formed on the semiconductor substrate with the same height. An interlayer insulating layer 152 and a peripheral bit line 150 are formed on the peripheral gate 140 and the peripheral bit line 150 includes a bit line contact 154, a bit line electrode 156 and a bit line hard mask 157. A nitride layer 158 which serves as an etching stopper in etching a lower electrode of the cell region is formed and a PSG (phosphorous silicate glass) layer 162 and a TEOS (plasma enhanced tetra ethyl ortho silicate) layer 164 that together serve as the sacrificial layer 160 in the capacitor formation process are sequentially formed over the nitride layer 158.

If the GBL process is used in fabricating a semiconductor device, there may develop a height difference between the cell region and the peripheral region of the sacrificial layer 160 in the process of forming the peripheral bit line 150. This height difference, which may be referred to as a step structure, may lead to a defect such as a seam in the sacrificial layer 160 between the cell region and the peripheral region. The seam defect may cause another defect such as a bridge between storage nodes in the storage node formation process.

So as to prevent the defects, a method of planarization-etching the PSG layer 162 through a chemical mechanical polishing (CMP) process may be performed. However, if the CMP process is performed such that the PSG layer 162 is exposed, a residue of the slurry used in the CMP process or a micro scratch may result in formation of bridges between the storage nodes.

### BRIEF SUMMARY OF THE INVENTION

Various embodiments of the invention may provide a semiconductor memory device and a method of manufacturing the same that forms a nitride layer with the same height as a peripheral bit line to remove the step between a cell region and a peripheral region. Accordingly, the structure of a sacrificial layer for a storage node may be reinforced and the damage of an interlayer insulating layer in the peripheral region may be prevented in a full dip out process by the nitride layer serving as spacers for protecting the interlayer insulating layer disposed under the nitride layer in a metal wiring formation process.

According to one aspect of an exemplary embodiment, a semiconductor device includes a semiconductor substrate including a cell region and a peripheral region, a buried gate formed to be buried in the semiconductor substrate of the cell region, a cell bit line disposed on the semiconductor substrate of the cell region, a peripheral gate disposed on the semiconductor substrate of the peripheral region, a peripheral bit line disposed on the peripheral gate in the peripheral region, and a nitride layer disposed in the cell region and the peripheral region with the same height as the peripheral bit line. Therefore, the step between the cell region and the peripheral region is removed to reinforce a structure of a sacrificial layer for a storage node.

Furthermore, the cell bit line and the peripheral gate may be disposed with the same height. The semiconductor device may include an interlayer insulating layer disposed under the peripheral bit line.

Furthermore, a thickness of the nitride layer may be substantially equal to a stacked thickness of the peripheral bit line and the interlayer insulating layer. The peripheral bit line may comprise tungsten (W). The semiconductor device may further include a sacrificial layer including a PSG layer and a TEOS layer and disposed on the nitride layer and the peripheral bit line.

The semiconductor device may further include a storage node hole formed in the sacrificial layer of a storage node region and a lower electrode formed within the storage node hole.

The semiconductor device may further include a passivation layer which is disposed over the peripheral bit line and the nitride layer and includes a low pressure nitride layer to prevent the nitride layer and the peripheral bit line from etching in a full deep out process.

Furthermore, the cell bit line may include a bit line contact connected to an active region of the semiconductor substrate in the cell region, a bit line electrode disposed on the bit line contact, a bit line hard mask disposed on the bit line electrode and spacers disposed on sidewalls of the bit line electrode and the bit line hard mask. The peripheral gate may have a GBL structure including a gate electrode disposed on the semiconductor substrate of the peripheral region, a gate hard mask disposed on the gate electrode and gate spacers disposed on the gate electrode and the gate hard mask.

According to one aspect of an exemplary embodiment, a method of manufacturing a semiconductor device includes providing a semiconductor substrate including a cell region and a peripheral region, forming a buried gate to be buried in the semiconductor substrate of the cell region, forming a cell bit line on the semiconductor substrate of the cell region, forming a peripheral gate on the semiconductor substrate of the peripheral region, forming a peripheral bit line on the peripheral gate in the peripheral region, and forming a nitride layer on the cell region and the peripheral region with the same height as the peripheral bit line. The step between the cell region and the peripheral region is removed to reinforce a sacrificial layer for a storage node.

Furthermore, the method may further include forming an interlayer insulating layer on the cell bit line and the peripheral gate, before forming a peripheral bit line.

The forming a nitride layer may include forming a nitride layer on a resultant of the semiconductor substrate including the peripheral bit line and planarization-etching the nitride layer by using the peripheral bit line as a target.

The planarization-etching the nitride layer may include performing using silica slurry or ceria slurry. The cell bit line and the peripheral gate may be simultaneously formed with the same height.

Furthermore, the forming a cell bit line and a peripheral gate may include forming a bit line contact on the semiconductor substrate of the cell region, forming a bit line electrode on the bit line contact in the cell region, forming a gate electrode on the semiconductor substrate of the peripheral region, forming a hard mask on the bit line electrode and the gate electrode, patterning the bit line electrode, the gate electrode and the hard mask and forming spacers on sidewalls of a patterned bit line electrode and patterned hard mask and sidewalls of a patterned gate electrode and a patterned hard mask.

Furthermore, the forming a peripheral bit line may include depositing a bit line material and etching the bit line material by using a photoresist layer as an mask through a photolithographic process.

The method may further include forming a sacrificial layer including a PSG layer and a TEOS layer on the nitride layer and the peripheral bit line, after forming a nitride layer.

Furthermore, the method may include forming a storage node hole by etching a portion of the sacrificial layer corresponding to a storage node region and forming a lower electrode within the storage node hole, after forming a sacrificial layer.

The method may further include removing the sacrificial layer by performing a cell dip out process or a full dip out process to form a cylinder type capacitor, after the forming a lower electrode.

Furthermore, the forming a storage node hole may include etching the sacrificial layer though a plasma etching process by using the mixture of gases such as, for example, CxFy, Ar and O₂, and etching the nitride layer through a plasma etching process by using a mixture of gases such as, for example, CHF₃, Ar and O₂. CxFy may be a suitable carbon-fluoride gas such as, for example, C₄F₆ or C₄F₈.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a sectional view of a prior semiconductor device.

FIG. 2 is a sectional view of a semiconductor device according to an exemplary embodiment of the inventive concept.

FIGS. 3 to 7 are sectional views sequentially illustrating a method of manufacturing a semiconductor device according to an exemplary embodiment of the inventive concept.

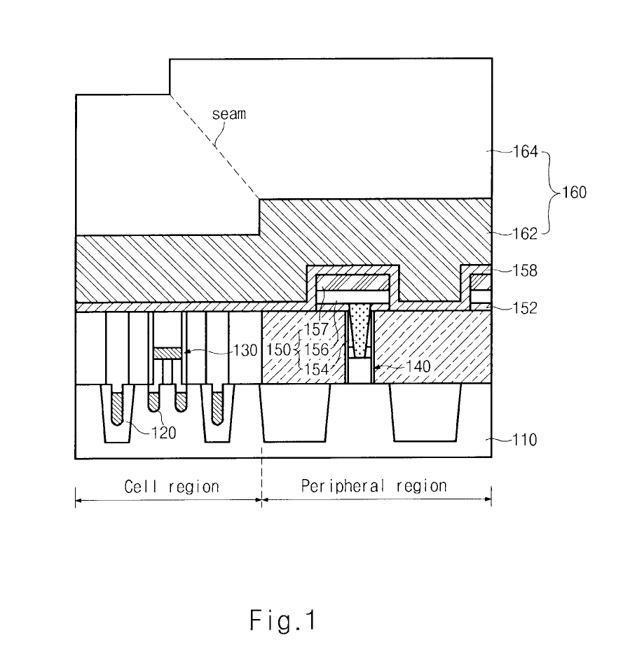

### DESCRIPTION OF EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as being limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a first layer is referred to as being “on” or “over” a second layer or substrate, the first layer can be directly on or over the second layer or substrate, or intervening layers may also be present between the first layer and the second layer or substrate.

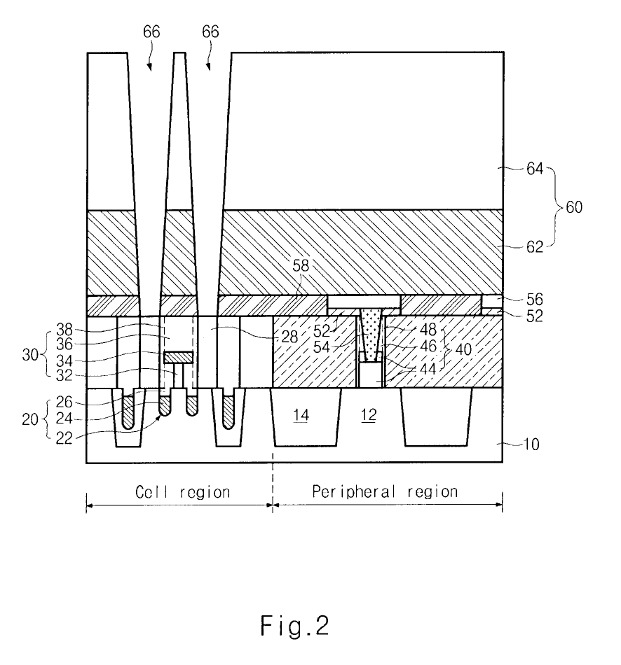

FIG. 2 is a sectional view of a semiconductor device according to an exemplary embodiment of the inventive concept. Referring to FIG. 2, a device isolation layer 14 defining active regions 12 is formed in a semiconductor substrate 10 including a cell region and a peripheral region. Buried gates 20 which are buried in the active region 12 and the device isolation layer 14 of the cell region in the semiconductor substrate 10 are formed. The buried gate 20 includes a recess 22 having a predetermined depth, a gate electrode 24 that is a conductive material is buried within a bottom of the recess 22, and a capping layer 26 disposed on the gate electrode 24 within the recess 22.

A cell bit line 30 in the cell region and a corresponding peripheral gate 40 in the peripheral region are disposed on the semiconductor substrate 10 with substantially the same height. The cell bit line 30 includes a bit line contact 32 connected to the active region 10, a bit line electrode 34 disposed on the bit line contact 32 and comprising conductive material, a bit line hard mask 36 disposed on the bit line electrode 34 and bit line spacers 38 disposed on sidewalls of the bit line electrode 34 and the bit line hard mask 36. The peripheral gate 40 also includes a gate electrode 44, a gate hard mask 46 and gate spacers 48. Furthermore, a storage node contact 28 which is to be connected to a storage node is disposed on the active region 12 of the cell region.

An interlayer insulating layer 52 is formed on the peripheral gate 40 at a predetermined thickness. A peripheral bit line 56 is disposed on the interlayer insulating layer 52 and a bit line contact 54 connected to the gate electrode 44 of the peripheral gate 40 and a bit line electrode 56.

A nitride layer 58 having a thickness substantially corresponding to the bit line electrode 56 of the peripheral bit line 50 and the interlayer insulating layer 52 is formed on the cell region so that the peripheral region has substantially the same height as the cell region. The sacrificial layer 60, comprising a PSG layer 62 and a TEOS layer 64, is formed on the nitride layer 58 in the cell region and the peripheral bit line 50. Storage node hole 66 is formed in the sacrificial layer 60 of the cell region.

Although the semiconductor device according to an exemplary embodiment adapts the GBL structure, as the nitride layer 58 that is substantially the same height as the peripheral bit line 50 is disposed on the cell region, there is no step structure between the cell region and the peripheral region. As a result, the step structure may not develop in the sacrificial layer 60. Accordingly, this may reduce, if not eliminate, defects such as seams near the interface between the cell region and the peripheral region.

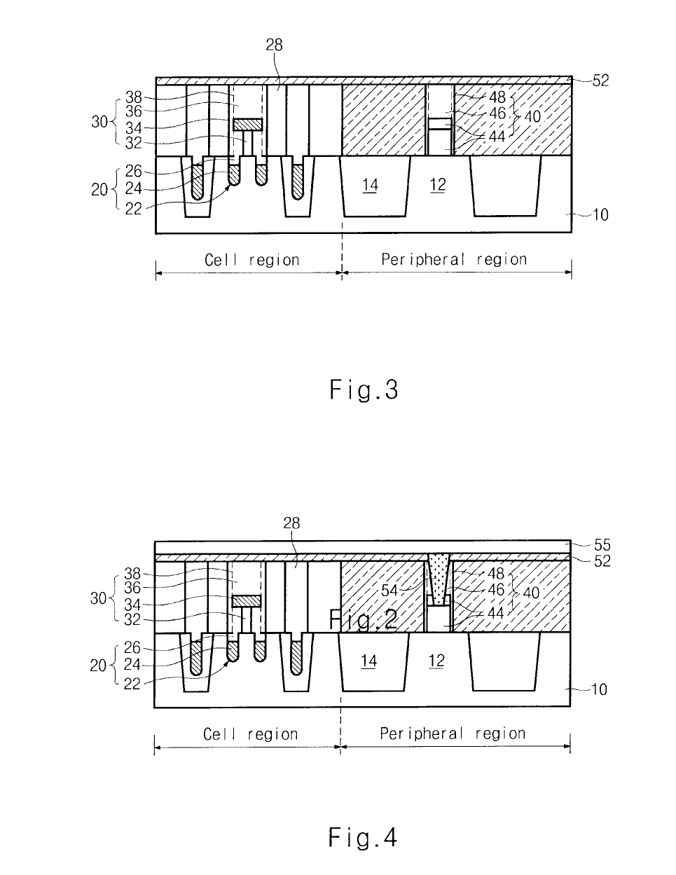

A method of manufacturing the semiconductor device having the structure as FIG. 2 according to an exemplary embodiment will be described hereinafter with reference to the accompanying drawings. FIGS. 3 to 7 are sectional views sequentially illustrating a method of manufacturing a semiconductor device according to an exemplary embodiment of the inventive concept.

Referring to FIG. 3, the device isolation layer 14 defining the active regions 12 is formed in the semiconductor substrate 10 including the cell region and the peripheral region. Next, the recesses 22 having a predetermined depth are formed in the semiconductor substrate 10 of the cell region. The gate electrode 24 and the capping layer 26 are sequentially buried within the recesses 22 to form the buried gates 20. The buried gate electrode 24 may comprise a conductive material such as, for example, W (tungsten), Ti (titanium), or TiN (titanium nitride), and the capping layer may comprise, for example, a nitride layer.

Subsequently, the cell bit line 30 and the peripheral gate 40 are formed. A polysilicon layer for the bit line contact 32 in the cell region and for the peripheral gate electrode 44 in the peripheral region is deposited at a predetermined thickness and an electrode material layer such as a metal layer for the bit line electrode 34 in the cell region and for the peripheral gate electrode 44 is deposited on the polysilicon layer. A hard mask (not shown) is formed on the electrode material layer and then the polysilicon layer and the electrode material layer are etched by using the hard mask as a mask. Next, spacers are formed on sidewalls of the patterned polysilicon layer and the patterned electrode material layer to form the cell bit line 30 and the peripheral gate 40.

Next, the interlayer insulating layer 52 is deposited on the cell bit line 30 and the peripheral gate 40 and planarized. The storage node contact 28 may be formed to connect to the active regions 12 in the cell region, either before or after the interlayer insulating layer 52 is formed.

Referring to FIG. 4, a portion of the interlayer insulating layer 52 in the peripheral region is etched and the bit line contact 54 is formed in the etched portion of the interlayer insulating layer 52 to be connected to the gate electrode 44 of the peripheral gate 40. A conductive layer 55 for a bit line electrode is formed on the bit line contact 54. The bit line contact 54 and the conductive layer 55 may comprise a conductive material such as, for example, polisilicon, W or Ti. The bit line contact 54 and the conductive layer 55 may comprise material such as, for example, tungsten (W).

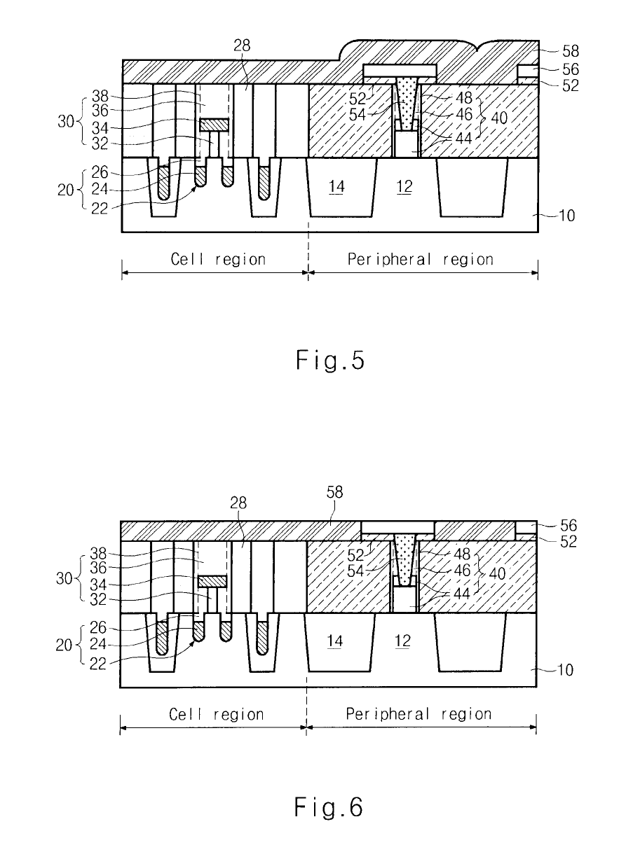

Referring to FIG. 5, a portion of the conductive layer 55 corresponding to the peripheral region may be patterned through a photolithographic process to form the peripheral bit line 56. At this time, a portion of the conductive layer 55 in the cell region is also removed. The patterning of the peripheral bit line 56 may comprise, for example, etching the conductive layer 55 through a photolithographic process using a photoresist layer as a mask. Next, the nitride layer 58 is deposited on an entire resultant of the semiconductor substrate 10 including the peripheral bit line 56.

Referring to FIG. 6, the nitride layer 58 may be planarization-etched by using the peripheral bit line 56 as a target to substantially coincide the height of the nitride layer 58 with the surface of the peripheral bit line 56. As a result, there may not be a substantial step structure between the cell region and the peripheral region and the nitride layer 58 is disposed in the space between the peripheral bit lines 56. A portion of the nitride layer 58 disposed in the peripheral region may serve to protect the interlayer insulating layer 52 which may comprise an oxide layer and disposed under the nitride layer 58. The planarization-etching of the nitride layer 58 may comprise performing a CMP process using ceria slurry or silica slurry. Although not shown in drawings, a low pressure nitride layer may be further formed on the nitride layer 58 and the peripheral bit line 56.

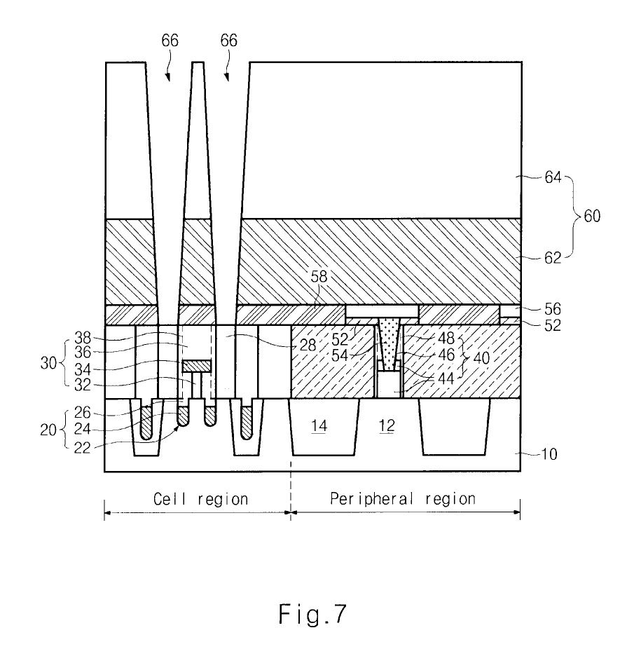

Referring to FIG. 7, the PSG layer 62 and the TEOS layer 64 are sequentially deposited on the planarized nitride layer 58 and the peripheral bit line 56 to form the sacrificial layer 60. Since a substantial step structure may not have formed in the precious steps, the sacrificial layer 60 may be evenly deposited so that a defect, such as a seam, may not be produced. Next, portions of the sacrificial layer 60 and the nitride layer 56 in the cell region are etched to form a storage node hole 66 exposing an upper portion of the storage node contact 28. At this time, as the sacrificial layer 60 comprises an oxide material, the sacrificial layer 60 may be plasma etched by using a mixture of gases such as, for example, CxFy, Ar and O₂, and the nitride layer 58 may be plasma etched by using a mixture of gases such as, for example, CHF₃, Ar and O₂. CxFy may be a carbon-fluorine gas such as, for example, C₄F₆ or C₄F₈.

Next, although not shown in drawings, a lower electrode, a dielectric layer and an upper electrode may be sequentially deposited within the storage node contact hole 66 to form a concave type capacitor. Alternately, after the lower electrode is formed, a cell dip out process that removes only a portion of the sacrificial layer 60 in the cell region or a full dip out process that removes all portions of the sacrificial layer 60 in the cell region and the peripheral region may be performed to remove the sacrificial layer 60, thereby forming a cylinder type capacitor.

When the full dip out process is performed, the nitride layer 58 and the peripheral bit line 56 are not removed by the chemical material used in the conventional full dip out process. However, if a chemical material which can etch the nitride layer 58 or the peripheral bit line 56 is used in the full dip out process, it may be necessary to form a low pressure nitride layer (not shown) on the nitride layer 58 and the peripheral bit line 56.

If a metal wiring is to be formed over the peripheral region, before the metal wiring is formed, a metal wiring contact connected to the peripheral bit line 56 may be formed. As a portion of the nitride layer 58 which is disposed on the sidewall of the peripheral bit line 56 may serve to protect the interlayer insulating layer 52 which is disposed under the peripheral bit line 56, when the contact hole for the metal wiring contact is formed, damage to the interlayer insulating layer 52 may be prevented.

The above embodiments of the present invention are illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims

What is claimed is:

1. A semiconductor device, comprising:
a buried gate buried in a semiconductor substrate; and
a nitride layer disposed over the buried gate, wherein upper portion of the nitride layer is at substantially the same height as an upper portion of a peripheral bit line.

2. The semiconductor device of claim 1, wherein a cell bit line and a peripheral gate disposed over the semiconductor substrate are formed with substantially the same height.

3. The semiconductor device of claim 1, further comprising:
an interlayer insulating layer disposed under the peripheral bit line.

4. The semiconductor device of claim 3, wherein a thickness of the nitride layer is substantially equal to the stacked thickness of the peripheral bit line and the interlayer insulating layer.

5. The semiconductor device of claim 1, wherein the peripheral bit line comprises tungsten.

6. The semiconductor device of claim 1, further comprising:
a sacrificial layer disposed over the peripheral bit line and the nitride layer, wherein the sacrificial layer comprises a PSG (phosphorous silicate glass) layer and a TEOS (plasma enhanced tetra ethyl ortho silicate) layer.

7. The semiconductor device of claim 6, further comprising:
a storage node hole formed in the sacrificial layer of a storage node region; and
a lower electrode formed in the storage node hole.

8. The semiconductor device of claim 1, further comprising:
a passivation layer disposed on the peripheral bit line and the nitride layer, wherein the passivation layer comprises a low pressure nitride layer.

9. The semiconductor device of claim 1, wherein a cell bit line disposed over the semiconductor substrate comprises:
a bit line contact connected to an active region of the semiconductor substrate;
a bit line electrode disposed on the bit line contact;
a bit line hard mask disposed on the bit line electrode; and
bit line spacers disposed on sidewalls of the bit line electrode and the bit line hard mask,
wherein a peripheral gate disposed over the semiconductor substrate comprises:
a gate electrode on the semiconductor substrate;
a gate hard mask disposed on the gate electrode; and
spacers disposed on sidewalls of the gate electrode and the gate hard mask.

10. A method of manufacturing a semiconductor device, comprising:
forming a buried gate in a semiconductor substrate;
forming a cell bit line on the semiconductor substrate;
forming a peripheral gate on the semiconductor substrate;
forming a peripheral bit line on the peripheral gate; and
forming a nitride layer over he buried gate with substantially the same height as the peripheral bit line.

11. The method of claim 10, further comprising:
forming an interlayer insulating layer on the cell bit line and the peripheral gate before the forming the peripheral bit line.

12. The method of claim 10, wherein the forming a nitride layer comprises:
depositing a nitride layer on a resultant structure of the semiconductor substrate including the peripheral bit line; and
planarizing the nitride layer by using the peripheral bit line as a target.

13. The method of claim 12, wherein the planarizing the nitride layer is performed by using one of: ceria slurry and silica slurry.

14. The method of claim 10, wherein the cell bit line and the peripheral gate are simultaneously formed with substantially the same height.

15. The method of claim 14, wherein the forming the cell bit line and the peripheral gate comprises:
forming a bit line contact in the semiconductor substrate;
forming a bit line electrode on the bit line contact and forming a gate electrode on the semiconductor substrate;
forming a hard mask on the bit line electrode and the gate electrode;
patterning the bit line electrode, the gate electrode and the hard mask; and
forming spacers over sidewalls of a patterned bit line electrode and a patterned hard mask and over sidewalls of a patterned gate electrode and a patterned hard mask.

16. The method of claim 10, wherein the forming a peripheral bit line includes:
depositing a bit line material; and
etching the bit line material through a photolithographic process using a photoresist as a mask.

17. The method of claim 10, further comprising:
forming a sacrificial layer comprising a PSG layer and a TEOS layer on the peripheral bit line and the nitride layer.

18. The method of claim 17, further comprising:
forming a storage node hole by etching a portion of the sacrificial layer corresponding a storage node region; and
forming a lower electrode within the storage node hole.

19. The method of claim 18, further comprising:
removing a sacrificial layer by performing one of: a cell dip out process and a full dip out process.

20. The method of claim 18, wherein the forming the storage node hole comprises:
etching the sacrificial layer by a plasma etching process by using a mixture of at least one of CxFy, Ar and O₂ gases, where in CxFy is one of C₄F₆ and C₄F₈; and
etching the nitride layer by a plasma etching process by using a mixture of at least one of CHF₃, Ar and O₂ gases.
